(19) United States
(12) Patent Application Publication
(10) Pub. No.: US 2009/0155942 A1
(43) Pub. Date: Jun. 18, 2009

(54) HYBRID METAL BONDED VERTICAL CAVITY SURFACE EMITTING LASER AND FABRICATING METHOD THEREOF

(76) Inventors: O Kyun KWON, Daejeon (KR); Mi Ran PARK, Daejeon (KR); Won Seok HAN, Daejeon (KR); Jong Hee KIM, Daejeon (KR); Hyun Woo SONG, Daejeon (KR)

Correspondence Address: LADAS & PARRY LLP, 224 SOUTH MICHIGAN AVENUE, SUITE 1600, CHICAGO, IL, 60604, US

(21) Appl. No.: 12/355,836

(22) Filed: Jan. 19, 2009

Related U.S. Application Data
(62) Division of application No. 11/179,954, filed on Jul. 12, 2005, now abandoned.

(30) Foreign Application Priority Data
Dec. 14, 2004 (KR) 10-2004-0105704

(51) Int. Cl. H01L 21/02

(52) U.S. Cl. 438/29; 257/E21.002

(57) ABSTRACT

Provided is a method of fabricating a vertical cavity surface emitting laser among semiconductor optical devices, comprising: bonding a dielectric mirror layer to an epi-structure having a mirror layer and an active layer; bonding these on a new substrate using a metal bonded method; removing the existing substrate; and fabricating a vertical cavity surface emitting laser on the new substrate. The method of fabricating the vertical cavity surface emitting laser is performed by moving and attaching a vertical cavity surface emitting laser to a new substrate using an external metallic bonding method, without electrically and optically affecting upper and lower mirrors and an active layer that constitutes the vertical cavity surface emitting laser. While using the existing method of fabricating the vertical cavity surface emitting laser, the VCSEL is fabricated by moving to a new substrate having good thermal characteristics so that good heat emission characteristics are accomplished, thus facilitating manufacture of the vertical cavity surface emitting laser having high reliability and good characteristics.

### CROSS-REFERENCE TO RELATED APPLICATION

This application claims priority to and the benefit of Korean Patent Application No. 2004-105704, filed Dec. 14, 2004, the disclosure of which is incorporated herein by reference in its entirety.

### BACKGROUND

1. Field of the Invention

The present invention relates to a semiconductor optical device capable of significantly improving characteristics of an optical device, and more specifically, to a vertical cavity surface emitting laser and a fabricating method thereof.

2. Discussion of Related Art

Compared to the existing edge emitting laser diode, a vertical cavity surface emitting laser (VCSEL) has a lower threshold current, a higher coupling efficiency based on a circular beam shape. In addition, the VCSEL can be mass-produced like the existing electronic device due to easiness in fabricating two-dimensional array devices and capability of a device test in a wafer state. Therefore, the VCSEL has been developed as a promising device that can replace the existing optical device in those fields such as optical communication networks and optical sensors, due to good performance and low cost.

To fabricate the VCSEL, a mirror layer having high reflectivity and a material having high optical gains are technologically required. In particular, in the case of a laser using laser light, a wavelength varies according to an application field, and thus an effective combination of material should be considered according to the wavelength suitable for each application field.

As an example, a VCSEL having a wavelength of 850 nm has been successfully commercialized with a semiconductor Distributed Bragg reflector having high reflectivity using a combination of GaAs/AlGaAs with a GaAs substrate, an active layer having high gains and good thermal characteristics.

However, in case of a VCSEL having a wavelength band of 1.3 μm and 1.5 μm, which is commonly used for communication, there is a lot of difficulty to use a GaAs/AlGaAs material.

Therefore, recently, the VCSEL is generally fabricated using an InGaAsP or InAlGaAs material on an InP substrate. In this case, growth of a multi-layer is required to obtain high reflectivity. Further, there is a problem in that a quaternary material such as InGaAsP and InAlGaAs has restricted device characteristics due to a low thermal conductivity 1/10 as low as that of a binary material such as GaAs. Therefore, various technical methods are attempted to develop the VCSEL in a long wavelength band while overcoming the above-mentioned problem.

A method of fabricating the VCSEL is largely classified into a monolithic method in which a structure having a mirror layer and an active layer is grown at once using a semiconductor epitaxial growth process and then fabricated using a semiconductor device process, and a hybrid method in which an optical gain active layer and a mirror layer are separately grown and then combined in a fabricating process. In the former caser, after the structure is already finished through growth, device fabrication is performed, thus having a merit of an extremely simplified manufacturing process, however, having difficulties in growing a thick mirror layer and improving thermal characteristics due to quaternary material. In the latter case, the structure is separately grown. In other words, a long wavelength gain material uses a quaternary material while the mirror layer uses a binary material such as GaAs/AlAs, thus achieving good thermal and optical characteristics. However, a complicated process for separately epi-growing elements followed by combining them into a vertical cavity surface emitting laser, e.g., a wafer bonding process should be performed, so that there are problems in that device reliability and throughput are degraded due to a fabrication bonding defect and thus the chip cost is increased.

### SUMMARY OF THE INVENTION

The present invention is directed to a vertical cavity surface emitting laser and a fabricating method thereof using easiness of a fabrication process of a metal bonded vertical cavity surface emitting laser to increase device reliability.

To accomplish the above-mentioned object, the present invention attempts to overcome technical complexity generated by a vertical cavity surface emitting laser based on the prior art, e.g. a crystal defect or a fabrication defect, such as reliability issues due to, for example, plastic deformation, in a wafer bonding method in which a mirror layer material and an active layer material are separately grown and a wafer is bonded during fabrication, or a metamorphic growing method followed by combining a dielectric mirror layer. In addition, the present invention attempts to significantly improve material restriction such as low thermal conductivity generated in a structure on the basis of a highly reliable lattice matched crystal growth as in the long wavelength band, through a device structure and a fabrication method thereof.

In particular, the prior art largely uses a wafer bonding process between heterogeneous materials such as GaAs—InAlGaAs or uses a metamorphic growth process in order to improve thermal characteristics that largely affect performance in operation of a vertical cavity surface emitting laser. However, with these methods, a bonding portion plays a much sensitive electrical and optical role in a laser structure, and further, contains defects due to wafer bonding. Thus, the device fabrication process is complicated and thus there arises a reliability problem due to the internal defects. Therefore, according to the present invention, on the basis of a homogeneous material that is stable in the vertical cavity surface emitting laser, the bonding between the laser portion and the substrate for improving thermal characteristics is placed out of the laser structure not to affect laser, and a bonding method introduces a way to enhance reliability using a metallic bonded method to provide a highly reliable and stable device structure and a much facilitated fabrication process.

One aspect of the present invention is to provide a vertical cavity surface emitting laser comprising: a substrate; a bonding layer formed on the substrate; a first mirror layer formed on the bonding layer; an active layer formed on the first mirror layer and stacked on first and second semiconductor electrode layers for injecting current; and a second mirror layer formed on the active layer, wherein crystal in the structure is grown by lattice matching.

Another aspect of the present invention is to provide a method of fabricating a vertical cavity surface emitting laser, the method comprising: forming a first mirror layer on a first substrate; forming a first semiconductor electrode layer on the first mirror layer; forming an active layer on the first semiconductor electrode layer; forming a second semiconductor electrode layer on the active layer; forming a second mirror layer on the second semiconductor electrode layer; forming a bonding layer on the second mirror layer to join a second substrate; removing the first substrate; partially etching the first mirror layer, the semiconductor electrode layer and the active layer to cause the first and second semiconductor electrode layers to be exposed; and forming the first and second metal ohmic layers on the first and second semiconductor electrode layers, wherein crystal in the structure is grown by lattice matching.

The crystal growth of the structure may be performed using homogeneous materials.

The first mirror layer may include a metal mirror layer formed on the bonding layer, and a dielectric mirror layer formed on the metal mirror layer.

The bonding layer may include a metal bonded layer.

### BRIEF DESCRIPTION OF THE DRAWINGS

The above and other features and advantages of the present invention will become more apparent to those of ordinary skill in the art by describing in detail exemplary embodiments thereof with reference to the attached drawings in which:

FIG. 1 is a cross-sectional view of a vertical cavity surface emitting laser according to a preferred embodiment of the present invention;

FIGS. 2A and 2B are cross-sectional views illustrating a method of fabricating a vertical cavity surface emitting laser according to a preferred embodiment of the present invention; and

FIGS. 3A and 3B are cross-sectional views of an additional manufacture process for improving characteristics of a vertical cavity surface emitting laser according to a preferred embodiment of the present invention.

### DETAILED DESCRIPTION OF PREFERRED EMBODIMENTS

The present invention will now be described more fully hereinafter with reference to the accompanying drawings, in which preferred embodiments of the invention are shown. This invention may, however, be embodied in different forms and should not be construed as limited to the embodiments set forth herein. Rather, these embodiments are provided so that this disclosure will be thorough and complete, and will fully convey the scope of the invention to those skilled in the art. In the following description, when it is described such that one layer is formed on the other layer, this may mean that the one layer is formed directly on the other layer, or the third layer may be interposed therebetween. In addition, thickness and size of each layer is exaggeratingly shown for the sake of illustration and clarity. In the drawings, like numerals refer to like elements.

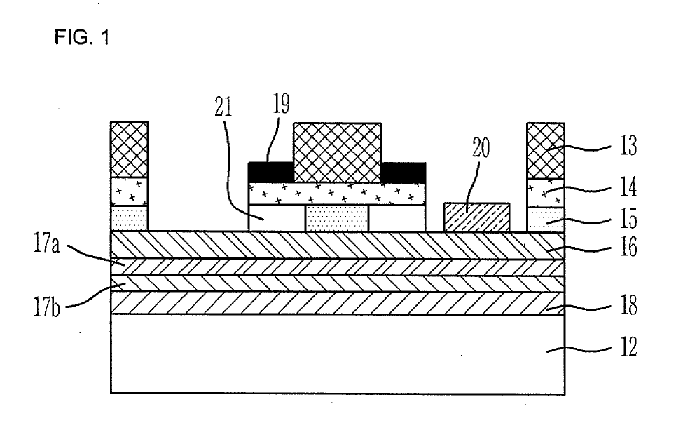

FIG. 1 is a cross-sectional view of a vertical cavity surface emitting laser according to a preferred embodiment of the present invention.

The vertical cavity surface emitting laser of FIG. 1 includes a substrate 12, a bonding layer 18, second mirror layers 17a and 17b, a second semiconductor electrode layer 16, an active layer 15, a first semiconductor electrode layer 14 and a first mirror layer 13 for emitting a laser beam of a predetermined wavelength through one mirror layer of both mirror layers. Here, the second mirror layers include a dielectric mirror layer 17a and a metal mirror layer 17b. In addition, the vertical cavity surface emitting laser includes first and second metal ohmic layers 19 and 20 formed on the first and second semiconductor electrode layers 14 and 16, and a current blocking layer 21 surrounding the side of the active layer 15 in the laser semiconductor.

The vertical cavity surface emitting laser according to an embodiment of the present invention has a structure in which the first mirror layer 13, the first semiconductor electrode layer 14, the active layer 15, the second semiconductor electrode layer 16 and the second mirror layers 17a and 17b are grown on a separate substrate, and then transplanted and attached to the substrate 12 using a predetermined bonding layer 18. In addition, the crystal growth of the structure is performed using homogeneous materials. Therefore, according to the present invention, there is provided a vertical cavity surface emitting laser having good thermal emission characteristics and reliability and easiness in fabrication.

The vertical cavity surface emitting laser and a fabricating method thereof according to an embodiment of the present invention will be described below in more detail.

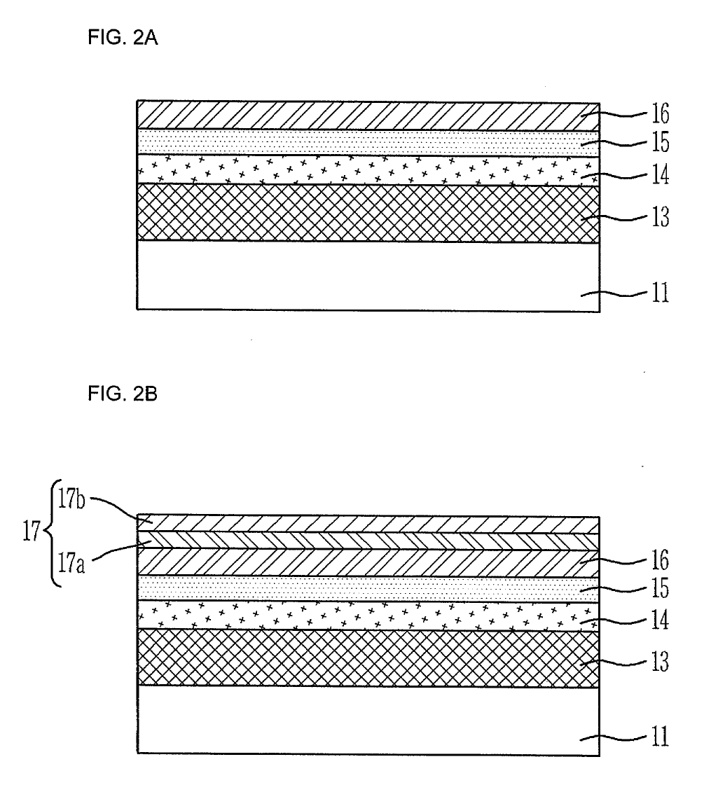

FIGS. 2A and 2B are cross-sectional views illustrating a method of fabricating a vertical cavity surface emitting laser according to a preferred embodiment of the present invention. FIG. 2A is a cross-sectional view of a vertical cavity surface emitting laser having a semiconductor Distributed Bragg reflector formed on a compound semiconductor substrate, and an electrode layer and an active layer for current injection; and FIG. 2B is a cross-sectional view of a dielectric mirror layer and a metal mirror layer stacked on the structure of FIG. 2A.

A method of fabricating the vertical cavity surface emitting laser according to the present invention is performed in the following order. First, as shown in FIG. 2A, a semiconductor Distributed Bragg reflector 13 is grown on a substrate 11 using a compound semiconductor epitaxial growth method to have the vertical cavity surface emitting laser, and then a first semiconductor electrode layer 14, an optical gain active layer 15, and a second semiconductor electrode layer 16 are grown one after another. At this time, the first and second semiconductor electrode layers 14 and 16 serves as an electrode for current injection and a heat emitter having good thermal characteristics. The active layer 15 serves as a gain layer for a laser operation. With the above operation, the final epi structure of the vertical cavity surface emitting laser except a second mirror layer is obtained. In an exemplary embodiment of the present invention, an InAlGaAs/InAlAs semiconductor Distributed Bragg reflector, InP first and second semiconductor electrode layers, and an InAlGaAs multi quantum-well structure active layer are used on an InP substrate.

Next, as shown in FIG. 2B, a dielectric multi-layer 17a and a metal mirror layer 17b are deposited on the epi structure formed in FIG. 2A, thus fabricating the second mirror layer 17. In an exemplary embodiment of the present invention, 2.5 pairs of Si/Al₂O₃ layers and Ti/Au (10 A/2000 A) metal layer are used, and a metal layer such as Ni and Pt is deposited to prevent a metallic atom diffusion problem in the subsequent process. Through the above operations, the vertical cavity surface emitting laser having the first and second mirror layers and the active layer, the first and second semiconductor electrode layers for current injection are obtained. In the structure according to the present invention, there is no defect caused by a bonding process between heterogeneous semiconductors, such as a GaAs/AlAs semiconductor Distributed Bragg reflector and an InP electrode layer, or metamorphic growth such as growth of GaAs/AlAs semiconductor Distributed Bragg reflector, so that a structure easy to fabricate is accomplished.

Further, while the laser structure is obtained in FIG. 2B, an InAlGaAs/InAlAs semiconductor Distributed Bragg reflector used as an example of the present invention has low thermal conductivity and a thick layer, so that it is not appropriate to sufficiently emit heat generated in device operation. A method of solving this problem is described below.

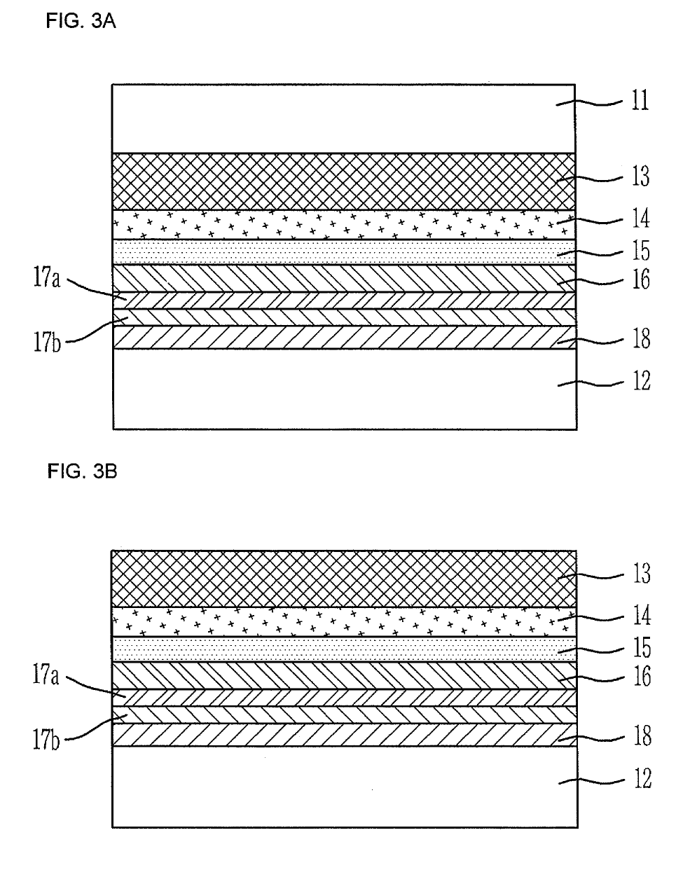

FIGS. 3A and 3B are cross-sectional views illustrating an additional manufacture process for improving characteristics of a vertical cavity surface emitting laser according to a preferred embodiment of the present invention. FIG. 3A is a cross-sectional view of a metal bonded structure in which a metallic bonding agency is deposited on a new substrate, added to the structure of FIG. 2B; and FIG. 3B is a cross-sectional view of a structure in which a compound semiconductor substrate is selectively etched and removed.

In the present embodiment, the second substrate 12 consisting of GaAs, AlN and Si, which have good thermal conductivity and are electrically insulated is added to the structure obtained in FIG. 2B through a metallic bonding process. To this end, as shown in FIG. 3A, a metallic bonding agency is deposited on a surface of the structure obtained in FIG. 2B and deposited on the second substrate 12 in the same manner, and then, constant pressure and temperature are applied to two surfaces contacting each other to derive metallic reaction, and thus, a strong and tight bonding layer is formed.

Here, as an example of the metallic bonding process, a semiconductor process is performed using a materials such as AuGe, AuSn, and Pd/In in an inert gas atmosphere in reaction, a pressure of less than 1 kg/cm², and a temperature of 200˜400° C. The metallic bonding portion serves to emit heat generated by operating the laser to the second substrate 12 having good thermal characteristics through a thin Si/Al₂O₃ dielectric mirror layer 17a, and to mechanically fix the laser structure to the second substrate 12, and thus, does not affect electrically and optically sensitive characteristics.

Next, as shown in FIG. 3B, the structure is transplanted to the second substrate 12, and then the first substrate 11 is removed. By removing the first substrate 11, the transplantation of the laser structure layer to the second substrate having good thermal conductivity is finished. The removal of the first substrate 11 is performed using a wet selective etching method in an HCl-based solution after mechanical lapping. As an example of the present embodiment, the HCl undiluted solution is used to remove the InP substrate 11.

Likewise, in the present invention, the metallic bonding portion exists out of laser, and thus, without having a defect in the laser, reliability of the vertical cavity surface emitting laser can be improved due to reliability of the metallic bonding itself, and temperature characteristic can be significantly improved due to good heat emission.

Next, a predetermined process is performed to fabricate the vertical cavity surface emitting laser shown in FIG. 1. For example, the first and second semiconductor electrode layers 14 and 15 for current injection are exposed to facilitate operation of the transplanted portion of the device, and the current blocking layer 21 is formed for current confinement. For example, through an etching process, portions of the first mirror layer 13, the first semiconductor electrode layer 14 and the active layer 15 are removed, and the current confinement forms the current blocking layer 21 using an air gap, ion implantation, and an oxide layer.

Specifically speaking, first, the first semiconductor electrode layer 14 is exposed by applying an Ar/Cl dry etching process for forming the first mesa to the first mirror layer 13, and the second mesa is formed on the first semiconductor electrode layer 14 through a dry etching process of CH₄:H₂ gas. Next, the active layer 15 exposed by the wet etching process is removed to expose the second semiconductor electrode layer 16. At this time, the exemplary current confinement uses an air gap, the current blocking layer 21 is formed by the implantation and the oxide layer partially oxidized, and the first and second ohmic metal layers 19 and 20 are deposited on the first and second exposed semiconductor electrode layers 14 and 16 to form the electrode, respectively. Through the above-mentioned process, the vertical cavity surface emitting laser shown in FIG. 1 is fabricated.

As described above, according to the present invention, a vertical cavity surface emitting laser is fabricated through a compound semiconductor growth method such that a semiconductor Distributed Bragg reflector, a first semiconductor electrode layer, an active layer, and a second semiconductor electrode layer are grown on a first substrate, and then a laser structure is finished using a second mirror layer including a dielectric multi layer and a metal mirror layer, and the final epi structure is obtained by attaching and transplanting the laser structure to the second substrate having good thermal characteristics using a metallic bonding method and then removing the first substrate. Therefore, the first substrate uses a semiconductor Distributed Bragg reflector having a required wavelength and a gain active layer as a medium, and then is moved to the second substrate having good thermal characteristic using a stable metallic bonding manner, thus advantageously reducing complexity of processes due to the conventional bonding between semiconductors, and reliability degradation generated by intrinsic defect. This leads to a device structure and a fabrication method thereof capable of significantly improving characteristic degradation due to the thermal characteristic and the low cost based on mass production.

Although exemplary embodiments of the present invention have been described with reference to the attached drawings, the present invention is not limited to these embodiments, and it should be appreciated to those skilled in the art that a variety of modifications and changes can be made without departing from the spirit and scope of the present invention.

What is claimed is:

1. A method of fabricating a vertical cavity surface emitting laser, the method comprising:
forming a first mirror layer on a first substrate;
forming a first semiconductor electrode layer on the first mirror layer;
forming an active layer on the first semiconductor electrode layer;
forming a second semiconductor electrode layer on the active layer;
forming a second mirror layer on the second semiconductor electrode layer;
forming a bonding layer on the second mirror layer to bond a second substrate;
removing the first substrate;
partially etching the first mirror layer, the semiconductor electrode layer and the active layer to cause the first and second semiconductor electrode layers to be exposed; and
forming the first and second metal ohmic layers on the first and second semiconductor electrode layers,
wherein crystal in the structure is grown by lattice matching.

2. The method according to claim 1, wherein the crystal growth is lattice-matched growth using homogeneous materials.

3. The method according to claim 1, wherein the forming the second mirror layer comprises:
forming a dielectric mirror layer on the second semiconductor electrode layer; and
forming a metal mirror layer on the dielectric mirror layer.

4. The method according to claim 1, wherein the forming the bonding layer on the second mirror layer to bond the second substrate comprises forming a metal bonded layer to bond the second substrate.
